(19) United States
(12) Patent Application Publication
(10) Pub. No.: US 2025/0311124 A1
(43) Pub. Date: Oct. 2, 2025

(54) DISPLAY APPARATUS FOR VEHICLE AND DRIVING METHOD THEREFOR

(71) Applicant: HYUNDAI MOBIS CO., LTD., Seoul (KR)

(72) Inventor: Kil Pyung JANG, Seoul (KR)

(73) Assignee: HYUNDAI MOBIS CO., LTD., Seoul (KR)

(21) Appl. No.: 19/057,172

(22) Filed: Feb. 19, 2025

(30) Foreign Application Priority Data
Apr. 2, 2024 (KR) 10-2024-0044872

(51) Int. Cl. H05K 5/02; B60R 11/00; B60R 11/02; H05K 7/20

(52) U.S. Cl. CPC H05K 5/0217; B60R 11/0235; H05K 7/20963; B60R 2011/0085; B60R 2011/0092

(57) ABSTRACT

A display apparatus for a vehicle, comprising: a display module comprising a display panel configured to display an image; a housing disposed adjacent to the display module and having an accommodation space; a mover connected to and configured to move the display module; a driving unit disposed at the accommodation space of the housing and configured to provide a driving force to the mover; and a controller configured to control the mover and the driving unit.

### CROSS-REFERENCE TO RELATED APPLICATIONS

This application claims the benefit of priority to Korean Patent Application No. 10-2024-0044872 filed in the Korean Intellectual Property Office on Apr. 2, 2024, the entire contents of which are incorporated herein by reference.

### TECHNICAL FIELD

The present disclosure relates to a display apparatus for a vehicle.

### BACKGROUND

The description in this section merely provides background information related to the present disclosure and does not constitute the related art.

A display apparatus that may provide various pieces of information about a vehicle may be installed in the interior of the vehicle, such as the center fascia, dashboard, or head lining. This display apparatus may provide not only various pieces of information about a vehicle, but also various pieces of entertainment content. For example, the display apparatus may play music or videos, receive terrestrial broadcasting or satellite broadcasting and display the same on the screen, provide information for the convenience of a user, such as vehicle status, weather, and news, and perform navigation.

The display apparatus may be configured as a large screen to provide various pieces of information and various pieces of entertainment content. This display apparatus may also be installed on the dashboard of a vehicle disposed in front of a driver seat and a passenger seat.

Since the installation location of the fixed display apparatus is fixed, the space utilization inside a vehicle is limited, and the larger the display size, the lower the forward visibility.

The movable display apparatus may move up and down or left and right relative to the dashboard. The display moves along the guide, allowing a driver and a front passenger to selectively use the display apparatus.

Various dynamic display apparatuses are being released to improve user convenience. When the dynamic display apparatus moves to optimize space, the lower space may be used as a storage space. In the case of a pop-up display apparatus, the display apparatus stored in the storage space may be pulled out and used when necessary.

In the case of a pop-up display apparatus, the instrument panel (IP) garnish is separated from the display apparatus, which reduces the sense of design integration.

When the IP garnish is located at an upper end of the display apparatus, interference occurs with the IP garnish when the display apparatus moves upward, which causes restrictions on the cockpit design of an upper portion of the display apparatus, such as the IP garnish having to be located behind the display apparatus.

### SUMMARY

A main purpose of an embodiment is directed to providing a display apparatus for a vehicle capable of efficiently retracting or pulling out the display apparatus utilized in the vehicle from a storage space.

Another main purpose of an embodiment is directed to providing a display apparatus for a vehicle with a swing structure that eliminates interference between the display apparatus and IP garnish, thereby improving the freedom of vehicle cockpit design at an upper portion of the display apparatus.

The aspects of the present disclosure are not limited to those mentioned above, and other aspects not mentioned herein will be clearly understood by those skilled in the art from the following description.

According to an embodiment, the display apparatus for the vehicle can efficiently allow the display apparatus utilized in the vehicle to be retracted into or pulled out from the storage space.

According to an embodiment, the display apparatus for the vehicle can eliminate interference between the display apparatus and the IP garnish, thereby improving the degree of freedom of the vehicle cockpit design at an upper portion of the display apparatus.

### BRIEF DESCRIPTION OF THE DRAWINGS

FIG. 1 is a combined perspective view of a display apparatus for a vehicle according to an embodiment of the present disclosure.

FIG. 2 is an exploded perspective view of a display apparatus for a vehicle according to an embodiment of the present disclosure.

FIG. 3 is a view showing movement of a display apparatus for a vehicle along direction B-B′ of FIG. 1 according to an embodiment of the present disclosure.

FIG. 4 is a view showing an operation example of a display apparatus for a vehicle along direction A-A′ of FIG. 1 according to an embodiment of the present disclosure.

FIG. 5 is a cross-sectional view taken along line A-A′ of FIG. 1 according to an embodiment of the present disclosure.

FIG. 6 is a flowchart showing a method of moving a display apparatus for a vehicle to an open state according to an embodiment of the present disclosure.

FIG. 7 is a flowchart showing a method of moving a display apparatus for a vehicle to a closed state according to an embodiment of the present disclosure.

### DETAILED DESCRIPTION

Hereinafter, some exemplary embodiments of the present disclosure will be described in detail with reference to the accompanying drawings. In the following description, like reference numerals preferably designate like elements, although the elements are shown in different drawings. Further, in the following description of some embodiments, a detailed description of known functions and configurations incorporated therein will be omitted for the purpose of clarity and for brevity.

Additionally, various terms such as first, second, A, B, (a), (b), etc., are used solely to differentiate one component from the other but not to imply or suggest the substances, order, or sequence of the components. Throughout this specification, when a part ‘includes’ or ‘comprises’ a component, the part is meant to further include other components, not to exclude thereof unless specifically stated to the contrary. The terms such as ‘unit’, ‘module’, and the like refer to one or more units for processing at least one function or operation, which may be implemented by hardware, software, or a combination thereof.

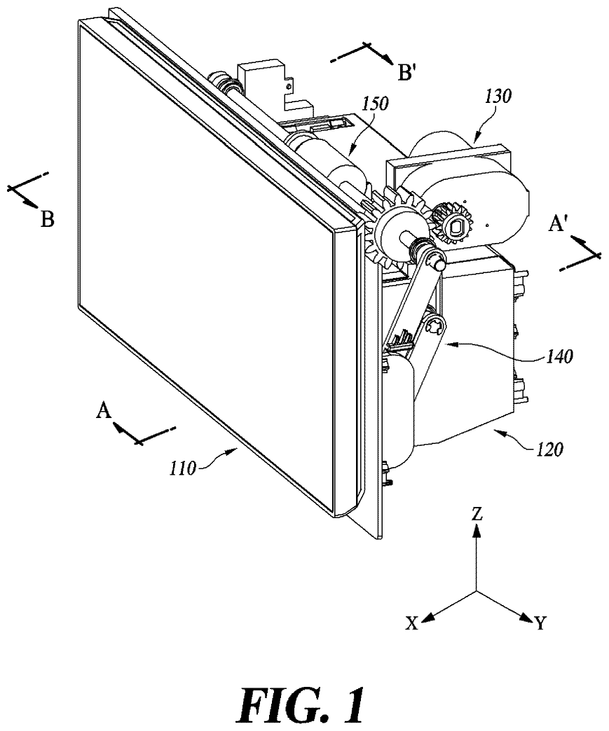

FIG. 1 is a combined perspective view of a display apparatus for a vehicle according to an embodiment of the present disclosure.

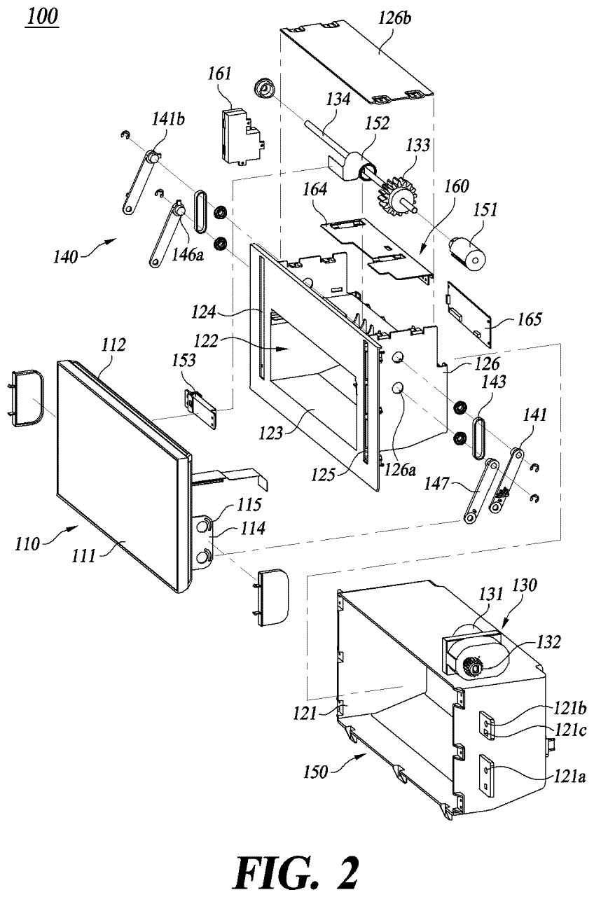

FIG. 2 is an exploded perspective view of a display apparatus for a vehicle according to an embodiment of the present disclosure.

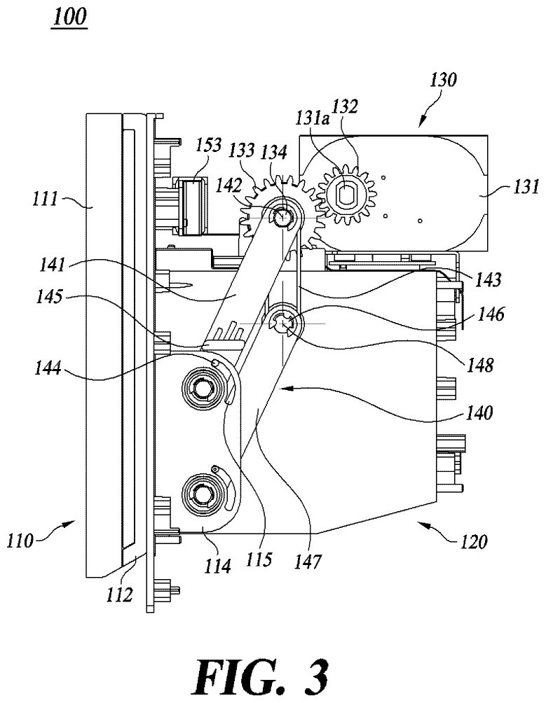

FIG. 3 is a view showing movement of a display apparatus for a vehicle along direction B-B′ of FIG. 1 according to an embodiment of the present disclosure.

Referring to FIGS. 1 and 2, a display apparatus 100 for a vehicle includes all or part of a display module 110, a housing 120, a driving unit 130, a mover 140, and a controller 160.

A display panel 111 of the display module 110 may include a display apparatus, LCD, LED, OLED, POLED, or other known display, which may receive signals from the integrated control system of a vehicle and output various pieces of information on a screen.

The display module 110 includes all or part of the display panel 111 and a back cover 112.

The display panel 111 is disposed on the front surface of the display module 110 and outputs the screen or displays an image.

The back cover 112 covers the display panel 111 on a rear surface of the display module 110.

Referring to FIG. 3, a closed state in which the display module 110 is retracted into the housing 120 and an open state in which the display module 110 is pulled out from the housing 120 are illustrated.

When the display module 110 is in a closed state, at least one surface of the back cover 112 is disposed to face one surface of the housing 120. When the display module 110 is in an open state, at least a part of the back cover 112 may be exposed to the outside.

The back cover 112 includes a first heat dissipation opening 113 to release heat generated from the display panel 111.

A control arm bracket 114 connected to a mover 140 is disposed at both ends of one surface of the back cover 112. The end of the control arm bracket 114 is configured in a form that is bent inwardly of the back cover 112, and the end of the control arm bracket 114 passes through the back cover 112 and is coupled to the other surface of the back cover 112.

The housing 120 is disposed adjacent to or in contact with one surface of the display module 110 and forms a receiving (or accommodation) space therein.

The housing 120 includes a storage portion 122 that is disposed adjacent to or in contact with one surface of the display module 110 inside the housing 120 and includes a storage space 123 that is open on the outside at least in one area, and a casing 121 that is disposed on a rear surface of the storage portion 122 and covers the storage portion 122.

The storage portion 122 has a moving hole 124 that extends in a height direction of the display module 110 so that the mover 140 may move at both ends of one surface of the storage portion 122 that faces the display module 110.

The mover 140 rotates by passing through the moving hole 124, and the display module 110 coupled to the control arm bracket 114 swings. Herein, the swing movement means a movement in which the display module 110 moves at a certain angle around a longitudinal axis of a main shaft 134.

A dust guard 125 mounted on the moving hole 124 is inserted into the moving hole 124 and fitted, and prevents foreign substances from entering the housing 120 when the display module 110 is in a closed state.

The dust guard 125 is made of an elastic material, and a groove is formed on one surface of the dust guard 125 so that the mover 140 may move when the display module 110 is in an open state.

The storage space 123 is formed by extending from one surface of the storage portion 122 in the other direction, and the storage space 123 is formed apart from an upper end of the housing 120 in a height direction.

When the display module 110 is in a closed state, the display module 110 covers an opening of the storage space 123, so that the storage space 123 is closed, and when the display module 110 is in an open state, the storage space 123 is in an open state.

A storage portion bracket 126 is disposed on both sides of the storage portion 122. A through hole 126a is formed on one surface of the storage portion bracket 126 so that the mover 140 may pass through.

A storage portion upper bracket 126b is disposed on an upper end of the storage portion 122 to protect the driving unit 130 and the mover 140.

A control printed circuit board (PCB) 165 that controls a motor 131, a position sensor 161, and a display PCB 164 may be disposed in an area at an upper end or a rear surface of the storage space 123.

For vibration durability, at least four screw fasteners 121a, at least two clip fasteners 121b, and at least two locator fasteners 121c are formed on both sides of the casing 121 and are mountable to a vehicle cockpit. However, the positions and quantities of the screw fasteners 121a, the clip fasteners 121b, and the locator fasteners 121c may be changed in consideration of the weight of the display apparatus, cockpit conditions, etc.

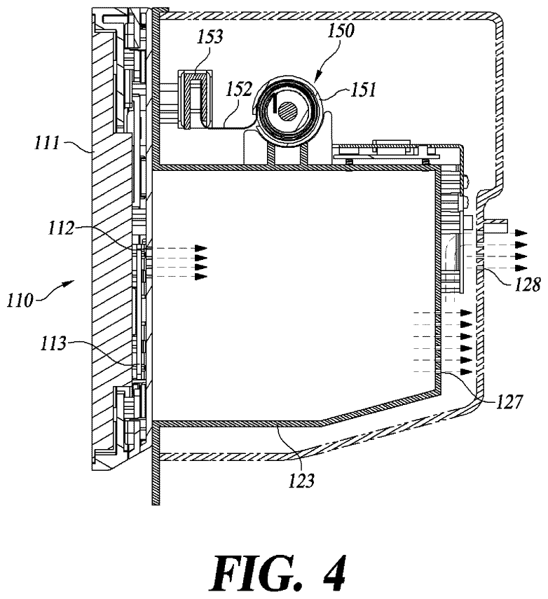

FIG. 4 is a view showing an operation example of a display apparatus for a vehicle along direction A-A′ of FIG. 1 according to an embodiment of the present disclosure.

Referring to FIG. 4, the driving unit 130 may be disposed at an upper end of the storage space 123 adjacent to the mover 140.

The driving unit 130 includes all or part of the motor 131, a drive gear 132, a power gear 133, and the main shaft 134.

The motor 131 is driven by an open signal transmitted by the controller 160 and generates a driving force. The motor 131 stops driving by a close signal transmitted by the controller 160.

The drive gear 132 rotates in the direction of a motor shaft 131a and is connected to the motor 131.

The power gear 133 is disposed adjacent to the motor 131 and the drive gear 132 so as to rotate by the driving force transmitted from the motor 131 and the drive gear 132.

The main shaft 134 is coupled to the power gear 133 to rotate by the rotation of the power gear 133, and extends in an axial direction of the motor 131.

The main shaft 134 passes through the through hole 126a of each storage portion bracket 126 located on both sides of the storage portion 122.

The display module 110 may pivot and swing with respect to (or about) the longitudinal axis of the main shaft 134 according to the rotation of the main shaft 134.

The mover 140 includes all or part of a first control arm 141 disposed adjacent to the storage portion bracket 126, a second control arm 147, a driving belt 143, and a sub-shaft 146.

The first control arm 141 is connected between the control arm bracket 114 coupled to one surface of the display module 110 and the main shaft 134.

A main shaft through hole 141b passing through the main shaft 134 is formed on one side of the first control arm 141. The main shaft through hole 141b extends along the longitudinal direction of the main shaft 134. The first control arm 141 rotates with respect to (or around) a first rotation axis 142 by the rotation of the main shaft 134.

The second control arm 147 is connected between the control arm bracket 114 and the driving belt 143 coupled to the first control arm 141.

A sub-shaft through hole 146a through which a sub-shaft 146 passes is formed on one side of the second control arm 147. The sub-shaft 146 is fixed to the storage portion bracket 126 so that the second control arm 147 rotates.

The driving belt 143 connects between the main shaft through hole 141b and the sub-shaft through hole 146a.

The second control arm 147 rotates with respect to (or around) a second rotation axis 148 by transmitting a rotational force of the main shaft 134 by the driving belt 143.

The display module 110 swings around the longitudinal axis of the main shaft 134 by the rotation of the first control arm 141 and the second control arm 147.

The first control arm 141 includes a locking pin 144 formed on one surface of the first control arm 141 so as to adjust the rotation angle of the first control arm 141. The locking pin 144 may be formed on one surface of the second control arm 147.

The control arm bracket 114 has a guide hole 115a located at one area of one surface of the control arm bracket 114 that contacts the first control arm 141 to correspond to the rotation angle of the first control arm 141 so as to limit a movement of the locking pin 144.

The guide hole 115b located at one area of one surface of the control arm bracket 114 to correspond to the rotation angle of the second control arm 147 may be formed.

The first control arm 141 includes a support bar 145 formed on one surface of the first control arm 141 and disposed adjacent to the locking pin 144.

The support bar 145 prevents the rotation of the display module 110 by restricting the rotation of the control arm bracket 114 when the display module 110 is pulled out from the housing 120 and is in an open state.

When an external force is applied to the display module 110, the display module 110 does not rotate clockwise due to the support bar 145.

When an external force is applied to the display module 110, the display module 110 does not rotate counterclockwise due to the locking pin 144.

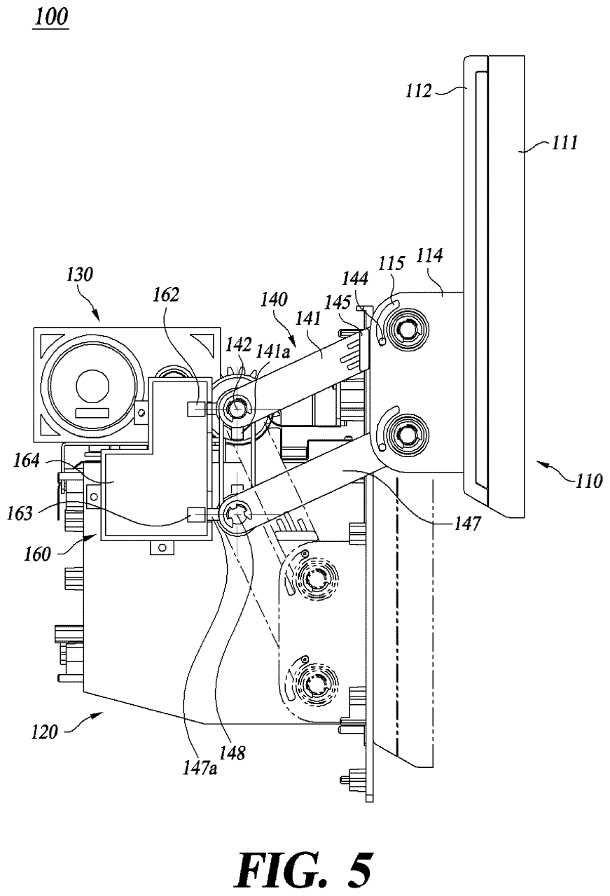

FIG. 5 is a cross-sectional view taken along line A-A′ of FIG. 1 according to an embodiment of the present disclosure.

Referring to FIG. 5, an elastic member 150 is coupled to a mover 140 to provide an auxiliary force to the mover 140. The elastic member 150 includes all or part of a first spring holder 151, a second spring holder 153, and a spiral spring 152.

The first spring holder 151 is disposed at an upper end of the storage space 123 and is coupled to the main shaft 134. The spiral spring 152 that rotates together with the main shaft 134 is mounted inside the first spring holder 151.

The second spring holder 153 is fixed to an upper end of the storage space 123, and the spiral spring 152 retracted into the first spring holder 151 is connected and fixed inside the second spring holder 153.

When the display module 110 is in a closed state, a second heat dissipation opening 127 is formed in an area at a rear surface of the storage space 123 of the storage portion 122 to release heat. The second heat dissipation opening 127 is disposed to correspond to the first heat dissipation opening 113.

A third heat dissipation opening 128 is formed in an area at a rear surface of the casing 121 to release heat to the outside. The third heat dissipation opening 128 is disposed to correspond to the second heat dissipation opening 127.

A flow path is formed to allow air to flow through the first heat dissipation opening 113, the second heat dissipation opening 127, and the third heat dissipation opening 128 inside the display apparatus 100 for the vehicle.

Referring to FIG. 3, the controller 160 controls the mover 140 and the driving unit 130 to control the movement of the display module 110.

The position sensor 161 transmits a signal to the controller 160 that controls the operation of the driving unit 130 according to the movement of the mover 140.

The position sensor 161 includes all or part of a switch a (or first switch) 162, a switch b (or second switch) 163, and a position circuit board 163.

The position sensor 161 is disposed on one surface of the storage portion bracket 126 and is disposed adjacent to the first control arm 141 and the second control arm 147.

The switch a 162 is configured to be in contact with a first contact protrusion 141a formed on one end of the longitudinal direction of the first control arm 141, and is disposed adjacent to the first rotation axis 142 on one surface of the position sensor 161.

When the display module 110 is in a closed state, the first contact protrusion 141a is disposed at a position in contact with the switch a 162. When the display module 110 is in an open state, the first contact protrusion 141a rotates counterclockwise at the switch a 162 corresponding to the angle at which the first control arm 141 rotates. In other words, when the display module 110 is in an open state, the first contact protrusion 141a does not contact the switch a 162.

The switch b 163 is configured to be in contact with a second contact protrusion 147a formed on one end of the longitudinal direction of the second control arm 147, and is disposed adjacent to the second rotation shaft 148 on one surface of the position sensor 161.

When the display module 110 is in a closed state, the second contact protrusion 147a is disposed to face the longitudinal direction of the driving belt 143. In other words, when the display module 110 is in a closed state, the second contact protrusion 147a does not contact the switch b 163. When the display module 110 is in an open state, the second contact protrusion 147a contacts the switch b 163.

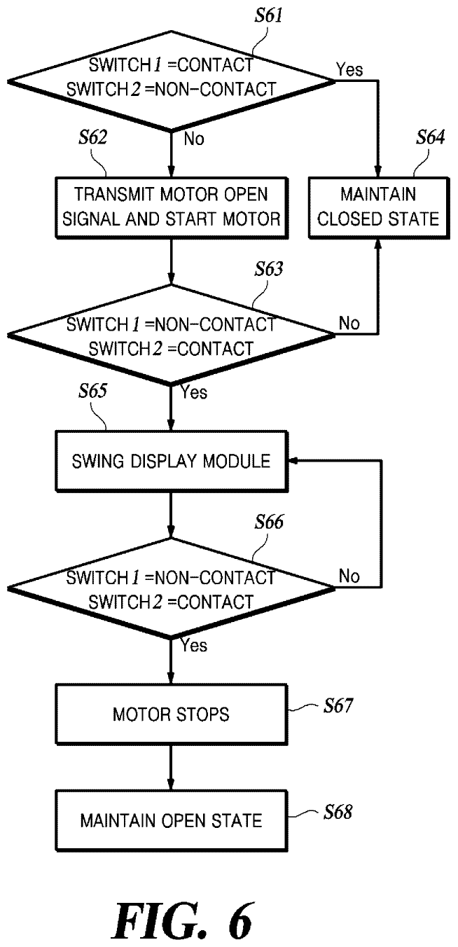

FIG. 6 is a flowchart showing a method of moving a display apparatus for a vehicle to an open state according to an embodiment of the present disclosure.

Referring to FIG. 6, the position sensor 161 senses whether the first contact protrusion 141a contacts the switch a 162 and the switch a 162 is turned on, and whether the second contact protrusion 147a does not contact the switch b 163 and the switch b 163 is turned off (S61).

When the first contact protrusion 141a contacts the switch a 162 and the switch a 162 is turned on, and the second contact protrusion 147a does not contact the switch b 163 and the switch b 163 is turned off, the motor 131 is not driven and the display module 110 is maintained in a closed state (S64).

When an open signal is transmitted to the motor 131 by the controller 160, the motor 131 is driven to rotate the first control arm 141 and the second control arm 147 (S62). In this connection, the first contact protrusion 141a does not contact the switch a 162, so that the switch a 162 is turned off, and the second contact protrusion 147a does not contact the switch b 163, so that the switch b 163 is also turned off (S63). In other words, the display module 110 swings in the direction of being pulled out from the housing 120 (S65).

When the first contact protrusion 141a does not contact the switch a 162, so that the switch a 162 is in an off state, and the second contact protrusion 147a contacts the switch b 163, so that the switch b 163 is in an on state, the position sensor 161 transmits a stop signal to the controller 160 (S66). The controller 160 stops driving the motor 131 (S67). In other words, the display module 110 maintains the open state (S68).

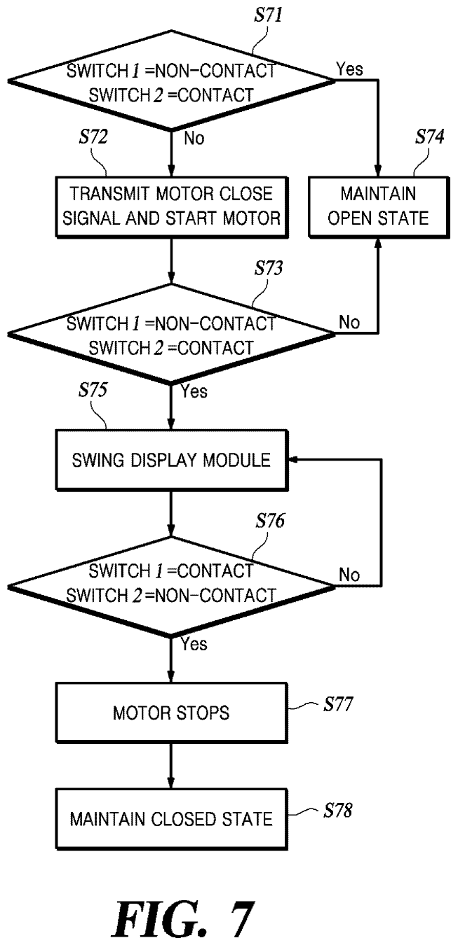

FIG. 7 is a flowchart showing a method of moving a display apparatus for a vehicle to a closed state according to an embodiment of the present disclosure.

Referring to FIG. 7, the position sensor 161 senses whether the first contact protrusion 141a does not contact the switch a 162 so that the switch a 162 is in an off state, and whether the second contact protrusion 147a contacts the switch b 163 so that the switch b 163 is in an on state (S71).

When the first contact protrusion 141a does not contact the switch a 162 so that the switch a 162 is in an off state, and the second contact protrusion 147a contacts the switch b 163 so that the switch b 163 is in an on state, the motor 131 is not driven and the display module 110 maintains the open state (S74).

When a close signal is transmitted to the motor 131 by the controller 160, the motor 131 is driven to rotate the first control arm 141 and the second control arm 147 (S72). In this connection, the first contact protrusion 141a does not contact the switch a 162, so that the switch a 162 is turned off, and the second contact protrusion 147a does not contact the switch b 163, so that the switch b 163 is also turned off (S73). In other words, the display module 110 swings in the direction of being retracted into the housing 120 (S75).

When the first contact protrusion 141a of the position sensor contacts the switch a 162 and the switch a 162 is turned on, and the second contact protrusion 147a does not contact the switch b 163 and the switch b 163 is turned off, the position sensor 161 transmits a stop signal to the controller 160 (S76). The controller 160 stops driving the motor 131 (S77). In other words, the display module 110 maintains a closed state (S78).

Although exemplary embodiments of the present disclosure have been described for illustrative purposes, those skilled in the art will appreciate that various modifications, additions, and substitutions are possible, without departing from the idea and scope of the claimed invention. Therefore, exemplary embodiments of the present disclosure have been described for the sake of brevity and clarity. The scope of the technical idea of the present embodiments is not limited by the illustrations. Accordingly, one of ordinary skill would understand that the scope of the claimed invention is not to be limited by the above explicitly described embodiments but by the claims and equivalents thereof.

What is claimed is:

1. A display apparatus for a vehicle, comprising:
a display module comprising a display panel configured to display an image;
a housing disposed adjacent to the display module and having an accommodation space;
a mover connected to and configured to move the display module;
a driving unit disposed at the accommodation space of the housing and configured to provide a driving force to the mover; and
a controller configured to control the mover and the driving unit.

2. The display apparatus of claim 1, wherein:
the housing comprises a storage portion disposed adjacent to the display module and having a storage space and an opening exposing the storage space externally of the housing,
the storage portion has a moving hole at a surface of the storage portion facing the display module and extending in a height direction of the display module to allow the mover to move, and
the storage space extends in a direction different from the height direction of the display module, and is spaced apart from an upper end portion of the housing in the height direction.

3. The display apparatus of claim 2, wherein:
the display module has a first heat dissipation opening,
the storage portion has a second heat dissipation opening at a rear surface of the storage space of the storage portion, the second heat dissipation opening disposed corresponding to the first heat dissipation opening,
the housing has a third heat dissipation opening at a rear surface of the housing, the third heat dissipation opening disposed corresponding to the second heat dissipation opening, and
an air flow path extends through the first heat dissipation opening, the second heat dissipation opening, and the third heat dissipation opening.

4. The display apparatus of claim 2, wherein the driving unit comprises:
a motor disposed adjacent to the mover and configured to generate the driving force;
a power gear disposed adjacent to the motor and configured to rotate when the driving force is transmitted from the motor; and
a main shaft coupled to the power gear and configured to rotate when the power gear rotates,
wherein the display module is configured to pivot and swing with respect to a longitudinal axis of the main shaft when the main shaft rotates.

5. The display apparatus of claim 4, wherein the mover comprises:
a first control arm connected between a control arm bracket coupled to the display module and the main shaft, and configured to rotate with respect to a first rotation axis when the main shaft rotates; and
a second control arm connected between the control arm bracket and a driving belt coupled to the first control arm, and configured to rotate with respect to a second rotation axis when a rotational force of the main shaft is transmitted to the driving belt,
wherein the display module is configured to swing with respect to the longitudinal axis of the main shaft when the first control arm and the second control arm rotates.

6. The display apparatus of claim 5, wherein:
the first control arm comprises a locking pin disposed on the first control arm and configured to adjust a rotation angle of the first control arm; and
the control arm bracket has a guide hole located at a surface portion of the control arm bracket that contacts the first control arm to correspond to the rotation angle of the first control arm and configured to limit a movement of the locking pin.

7. The display apparatus of claim 6, wherein the first control arm further comprises a support bar disposed on the first control arm and adjacent to the locking pin, the support bar configured to prevent the display module from rotating by restricting rotating of the control arm bracket when the display module is pulled out from the housing and in an open state.

8. The display apparatus of claim 5, further comprising an elastic member coupled to the mover and configured to provide auxiliary force to the mover, wherein the elastic member comprises:
a first spring holder disposed at an upper end of the storage space and coupled to the main shaft to rotate together with the main shaft;
a spiral spring disposed within the first spring holder and configured to rotate together with the main shaft; and
a second spring holder fixed to the upper end of the storage space and connected to the first spring holder by the spiral spring.

9. The display apparatus of claim 5, further comprising a position sensor disposed adjacent to the first control arm and the second control arm, wherein the position sensor comprises:
a first switch in contact with a first contact protrusion formed on a longitudinal end of the first control arm and disposed adjacent to the first rotation axis on the position sensor; and
a second switch in contact with a second contact protrusion formed a longitudinal end of the second control arm and disposed adjacent to the second rotation axis on the position sensor.

10. A method for driving the display apparatus for the vehicle according to claim 1, the method comprising:
a process in which, when a first contact protrusion contacts a first switch and the first switch is turned on, and a second contact protrusion does not contact a second switch and the second switch is turned off, a motor is not driven and a display module is maintained in a closed state retracted into the housing;
a process in which, when an open signal is transmitted to the motor by a controller, the motor is driven to rotate a first control arm and a second control arm, the first contact protrusion does not contact the first switch, so that the first switch is turned off, and the second contact protrusion does not contact the second switch, so that the second switch is also turned off, thereby swinging the display module; and
a process in which, when the first contact protrusion does not contact the first switch, so that the first switch is turned off, and the second contact protrusion contacts the second switch, so that the second switch is turned on, the motor stops driving and the display module maintains an open state pulled out from the housing.
